(19) United States
(12) Patent Application Publication
(10) Pub. No.: US 2001/0038315 A1
(43) Pub. Date: Nov. 8, 2001

(54) Method for generating a frequency by means of a PLL circuit

(76) Inventors: Bernd Memmler, Ottobrunn (DE); Reimund Rebel, Eppingen (DE); Karsten Thoelmann, Heilbronn (DE)

Correspondence Address: FASSE PATENT ATTORNEYS, P.A., P.O. BOX 726, HAMPDEN, ME, 04444-0726, US

(21) Appl. No.: 09/844,782

(22) Filed: Apr. 27, 2001

(30) Foreign Application Priority Data
May 5, 2000 (DE) 100 28 069.2

(51) Int. Cl. H03L 7/18

(52) U.S. Cl. 331/14; 331/25

(57) ABSTRACT

1. Method for generating a frequency by means of a PLL circuit

2.1. In known PLL circuits, the output signal at the phase detector is changed in order to accelerate the transient oscillation to the desired frequency.

2.2. In this method, the two comparison frequencies, which are fed to the phase detector, are simultaneously changed by factors via at least one switch. For coarse adjustment, the comparison frequencies are raised by a factor which accelerates the tuning process. Then, the increased comparison frequencies are lowered again by a factor for fine tuning, which defines the increments.

2.3. The method for frequency tuning PLL circuits is primarily used where a frequency change must take place quickly and inaudibly, for example in RDS applications in radio devices where it is advantageous.

The present invention relates to a method for generating an oscillation with a nominal frequency by means of a PLL (phase locked loop) circuit according to the preamble of patent claim 1.

### BACKGROUND OF THE INVENTION

Previous PLL circuits comprise an oscillator, hereinafter referred to as a reference oscillator, for making a reference frequency available, a voltage-controlled oscillator, hereinafter referred to as a VCO (voltage control oscillator), which generates an oscillation which has an output frequency which is regulated to a nominal frequency. Furthermore, the PLL circuit has one or a plurality of frequency dividers, which divide the tappable output frequency at the output of the VCO in order to compare the oscillation obtained in this way with the reference oscillation, which is also obtained via a frequency divider, in respect of its phase and thus also its frequency, a phase detector, which performs this comparison, and a drive comprising a charging pump and a loop filter which converts the pulse of the phase detector into a direct voltage. This direct voltage serves as the control voltage for the VCO. The output frequency of the freely oscillating VCO is stepped down with at least one of the frequency dividers to a first comparison frequency, and fed to the phase detector together with a highly constant second comparison frequency which is supplied from the reference oscillator via one of these downstream frequency dividers.

The disadvantage with this is that this circuit has unfavorable changeover characteristics. The transient time becomes very long if low reference frequencies are selected. Higher comparison frequencies and thus larger increments must be selected in order to achieve short transient times.

In order to suppress system-caused interference, such as the phase noise of a PLL circuit for example, the PLL circuit should have a high time constant in the loop filter together with a low comparison frequency. However, this conflicts with the fact that a fast frequency change requires the smallest possible time constant in the loop filter.

In order to obtain the fastest possible frequency change under the given conditions, either the current in the charging pump can be switched over during the change or the filter can be switched over during the frequency change. In both cases, the time constant of the filter is reduced in order to perform a faster frequency change with temporarily increased phase noise.

In DE 40 08 245 A1, the control voltage of the VCO is tapped in order to perform a fast frequency change and, via a distribution amplifier with a high impedance input and always one capacitor, fed to the inputs of the controllable current sources, in particular charging pumps.

A circuit arrangement is disclosed in DE 35 44 622 A1 for a conventional PLL circuit with a reduced locking-in time, in which a control device amplifies the control signal for the VCO as a function of the output signal of the phase detector.

A PLL circuit is disclosed in DE 42 32 609 A1 in which the frequency dividers have synchronization inputs and synchronization devices which emit a synchronization pulse at a defined time after the frequency change.

However, the disadvantage of this method is that the minimum time for the frequency change in this method is still limited by the comparison frequency, because the change to the new frequency requires a minimum number of frequency comparisons before the new frequency is tuned in.

Furthermore, the cost and circuit requirements for fast PLL circuits with low phase noise are high.

The object of the invention is to perform a fast frequency change despite a specified low comparison frequency with a low circuit requirement.

### SUMMARY OF THE INVENTION

The object of the invention is solved by the features described in the characterizing clause of patent claim 1. In which the divider factors of the frequency dividers are first lowered for the coarse adjustment in order to temporarily raise the comparison frequency, and then the unchanged divider factors are used for the fine tuning, for which the comparison frequency is so low that the required increment is achieved.

The advantage of the invention lies in the elimination of the restriction imposed by the comparison frequency. Fast frequency changes can be performed without suffering worse phase noise. The two comparison frequencies can also be synchronized more quickly. Furthermore, this accelerated transient oscillation of the output frequency to the desired nominal frequency can be performed economically and simply.

Advantageous further developments are derived from the subclaims. In which the PLL circuit is equipped with at least one switch with which the divider factors for adjusting the comparison frequency can be raised simultaneously. Furthermore, the switching device is automatically controlled by the phase detector. In doing so, the comparison frequency does not increase by just one factor, but the factor for raising the comparison frequency is changed as a function of the result of the phase detector during a tuning process. The method is not only particularly advantageous in conjunction with a conventional PLL circuit, but can even be improved with the aid of a fractional PLL circuit.

The invention is described in more detail in the following with the aid of two embodiments and figures. They show:

### BRIEF DESCRIPTION OF THE DRAWINGS

FIG. 1: fast PLL circuit

FIG. 2: fast fractional PLL circuit

### DESCRIPTION OF THE PREFERRED EMBODIMENTS

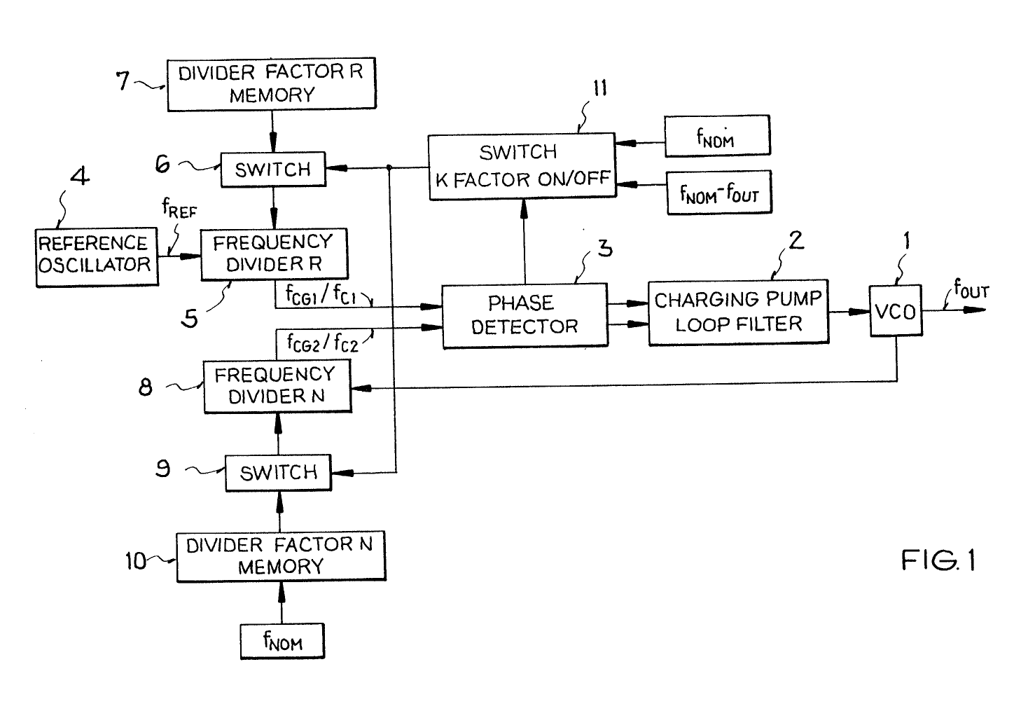

FIG. 1 shows a fast PLL circuit. In which a voltage-controlled oscillator 1, hereinafter referred to as VCO, generates an oscillation with the variable frequency f_{OUT}, which is available at the output of the PLL circuit. This output frequency f_{ouT} is to be regulated to a nominal frequency f_{NOM}. In the embodiment, the output frequency f_{OUT}=80 MHz and the nominal frequency to be set is f_{NOM}=100.0125 MHz. Divider factors R and N are assigned to each nominal frequency f_{NOM} in one or a plurality of memories 7, 10, as only fractions of the frequencies should be compared with one another because of the increments required. In this embodiment, one divider factor R is assigned to a reference frequency f_{REF} and the other divider factor N to the output frequency f_{ouT} The reference frequency f_{REF} is generated in a reference oscillator 4. It is constant and is characterized by being very pure and stable. In the embodiment f_{REF}=4 MHz. The divider factors R, N determine the division ratio of the frequency dividers 5, 8 with which the reference frequency f_{REF} and the output frequency f_{OUT} change, in particular they are lowered. In the embodiment, the divider factors for a nominal frequency f_{NOM}=100.0125 MHz are: N=8001 and R=320. If the switching devices 6, 9 are not activated, then the frequency divider 5 generates a constant first comparison frequency f_{C1}=12.5 kHz from the constant reference frequency f_{REF}=4 MHz, and the other frequency divider 8 generates a second changeable comparison frequency=9.99875 kHz from the changeable output frequency f_{OUT}=80 MHz. These two comparison frequencies f_{C1}, f_{C2} are compared in the phase detector 3. The digital phase detector 3 is linked to a drive 2 with which the VCO 1 is driven. Digital phase detectors emit a control signal whose direction and duration correspond to the phase shift of the two comparison frequencies f_{C1}, f_{C2}. In the simplest case, three signals may be available at the output of the phase detector as a result of the comparison, such as “+1”,“−1”, “0”, for example. In the case “+1”, the voltage in the drive 2, comprising charging pump and loop filter, is raised for the VCO 1, whereby the output frequency f_{OUT} of the VCO 1 is also raised. In the case “−1”, the voltage in the drive 2 for the VCO 1 is lowered, whereby the output frequency of the VCO is also lowered, and in the case “0”, the phases of the comparison frequencies f_{C1}, f_{C2} coincide. In order to accelerate this control procedure until the phases of the two comparison frequencies f_{C1}, f_{C2} coincide, the two divider factors R and N, which determine the division ratios of the frequency dividers 5, 8, are additionally reduced by the same factor e.g.: K=4 via a switch 11, which is linked to the phase detector 3. This switch 11 is always activated if:

a frequency change to another nominal frequency is performed and/or

the phase detector detects a larger difference between the two comparison frequencies f_{C1}, f_{C2}.

The switch 11, which is linked to two further switching devices 6 and 9, activates the coarse adjustment of the nominal frequency f_{NOM} by simultaneously activating the two switching devices 6, 9, which increase the divider factors R, N by the same factor K. In the simplest case, shift registers 6, 9, which can shift the divider factors bit by bit, are used for this. If the divider factors are thereby reduced by a factor of K=4, for example, then this gives new divider factors in which N=2000 and R=80, and thus higher comparison frequencies f_{CG1}=50 kHz and f_{CG2}=40 kHz for the phase detector. The transient oscillation to the first higher comparison frequency f_{CG}, takes place more quickly because more phase comparisons per second are possible at the higher frequencies f_{CG2}, f_{CG1}. The frequencies are synchronized more quickly. Once the transient procedure has been completed on the basis of the higher comparison frequencies f_{CG2}, f_{CG1}, that means f_{CG2}=f_{CG1}, then the switch 11 either switches itself off automatically, e.g. with the aid of the phase detector 3, or it is switched off manually, so that the frequency dividers 6, 9 are reset to their original division ratio with the original divider factors N=8001 and R=320. Nevertheless, the two lower comparison frequencies f_{C2}, f_{C1} then lie very close to one another, f_{C2}≈f_{C1}, so that the frequency tuning takes place very quickly in small increments as fine tuning. If the phase detector 3 then indicates that the phases of the two reference voltage match, then the output frequency f_{OUT} is equal to the nominal frequency f_{NOM}. In order to perfect this method, it is also conceivable to vary the factor K, by which the comparison frequencies f_{C2}, f_{C1} are increased, several times during tuning and in fact, for example, as a function of the difference between the nominal frequency and the output frequency f_{NOM}, f_{OUT}.

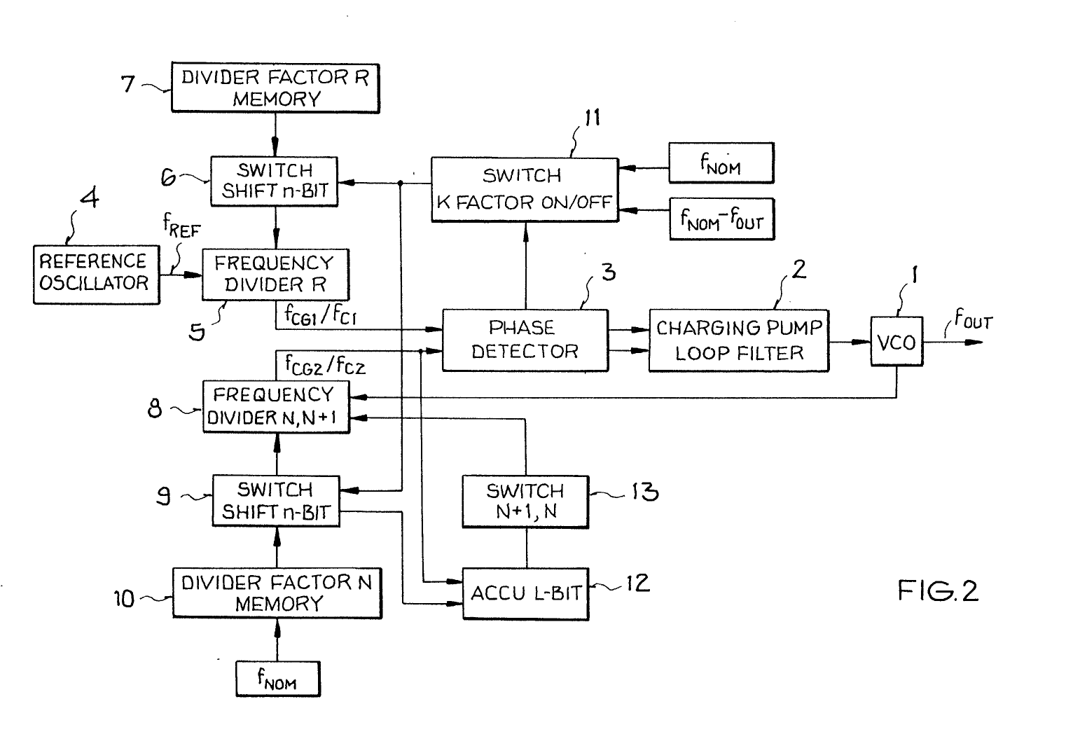

FIG. 2 shows a fast fractional PLL circuit. In which a voltage-controlled oscillator 1, hereinafter referred to as VCO, generates an oscillation with the variable frequency f_{OUT}, which is available at the output of the PLL circuit. This output frequency f_{OUT} should be regulated to a nominal frequency f_{NOM}. In the embodiment, the output frequency is f_{OUT}=80 MHz and the nominal frequency to be set is f_{NOM}=100.0125 MHz. Divider factors R, N and AC are assigned to each nominal frequency f_{NOM} in one or a plurality of memories 7, 10, as only fractions of the frequencies should be compared with one another because of the increments required. The two divider factors N and AC serve to determine the average value of the N− and N+1 fractions of the output frequency, as is usual for fractional PLL circuits. The average value is determined with the aid of the AC value available at the ACCU. This gives the second comparison frequency f_{C2}, which is set exactly to the fraction of the reference frequency. In this embodiment, the second comparison frequency is set exactly to the first comparison frequency. One of the divider factors R is assigned to the reference frequency f_{REF} and the other divider factor N or N+1 simultaneously to the output frequency f_{OUT}. The reference frequency f_{REF} is generated in a reference oscillator 4. It is constant and is characterized by being very pure and stable. In the embodiment this f_{REF}=4 MHz. The divider factors R, N and AC determine the division ratio of the frequency dividers 5, 8 with which the reference frequency f_{REF} and the output frequency f_{OUT} are changed. In the embodiment, the divider factors for a nominal frequency f_{NOM}=100.0125 MHz are: N=8001 or AC=0 R=320.

If the switching devices 6, 9 are not activated, then the frequency divider 5 generates a constant first reference frequency f_{C1}=12.5 kHz from the constant reference frequency f_{REF}=4 MHz, and the other frequency divider 8 generates a second changeable reference frequency=9.99875 kHz from the changeable output frequency f_{OUT}=80 MHz. In the fractional PLL circuit, the frequency divider 8 is linked to an N, N+1 switch 13, which, in turn, is influenced by an L-bit ACCU 12 and the desired nominal frequency. The L-bit ACCU 12 is controlled from the switch 0 by the second comparison frequency at the output of the frequency divider 8 and by the desired nominal frequency. These two comparison frequencies f_{C1}, f_{C2} are compared in the phase detector 3. The phase detector 3 is linked to a drive 2 with which the VCO 1 is driven. The phase detector emits a control signal whose direction and duration correspond to the phase shift of the two comparison frequencies f_{C1}, f_{C2}. In the simplest case, three signals may be available at the output of the phase detector as a result of the comparison, such as “+1”, “−1”, “0” for example. In the case “+1”, the voltage in the drive 2 is raised for the VCO 1, whereby the output frequency f_{OUT} of the VCO 1 is also raised. In the case “−1”, the voltage in the drive 2 for the VCO 1 is lowered, whereby the output frequency of the VCO is also lowered, and in the case “0”, the phases of the comparison frequencies f_{C1}, f_{C2} coincide. In order to accelerate this control procedure until the phases of the two comparison frequencies f_{C1}, f_{C2} coincide, the two divider factors R and N, which determine the division ratios of the frequency dividers 5, 8, are additionally reduced by the same factor, e.g.: K=4 via a switch 11, which is linked to the phase detector 3. At the same time, the value AC is set to the remainder of the N/K division. This switch 11 is always activated if:

a frequency change to another nominal frequency is performed and/or

the phase detector detects a larger difference between the two comparison frequencies f_{C1}, f_{C2}.

The switch 11, which is linked to two further switching devices 6 and 9, activates the coarse adjustment of the nominal frequency f_{NOM} by simultaneously activating the two switching devices 6, 9, which increase the divider factors R, N by the same factor K and simultaneously determine the value AC. The “fractional” mode is thus activated. In the simplest case, shift registers 6, 9, which can shift the divider factors bit by bit, are used for this. If the divider factors are thereby reduced by a factor of K=4, for example, then this gives new divider factors in which N=2000 and N+1=2001 AC=1 and R=80, and thus higher comparison frequencies f_{CG1}=50 kHz and f_{CG2}≈39.99 kHz for the phase detector. The transient oscillation to the first higher comparison frequency f_{CG10} takes place more quickly because more phase comparisons per second are possible at the higher frequencies f_{CG2}, f_{CG1}. The frequencies are synchronized more quickly. Once the transient procedure has been completed on the basis of the higher comparison frequencies f_{CG2}, f_{CG1}, that means f_{CG2}=f_{CG1}, the switch 11 either switches itself off automatically, e.g. with the aid of the phase detector 3 or it is switched off manually, so that the frequency dividers 6, 9 are reset to their original division ratio with the original divider factors N=8001 and R=320. With a fractional PLL circuit, in contrast to the embodiment shown in FIG. 1, the two lower comparison frequencies f_{C2}, f_{C1} are then exactly the same and f_{C2}=f_{C1}, so that a fine tuning is no longer necessary. The phase detector 3 will now indicate a still faster tuning of the phases of the two lower reference voltages f_{C2}, f_{C1}, whereby the adjustment of the output frequency f_{OUT} to the nominal frequency f_{NOM} is completed. The reduced transient time of a fractional PLL can thereby be used without having to accept its disadvantages in continuous operation. In order to perfect this method, the factor K, by which the comparison frequencies f_{C2}, f_{C1} are raised, may be varied several times during a tuning process and in fact, for example, as a function of the difference between the nominal frequency and the output frequency f_{NOM}, f_{OUT}.

What is claimed is

1. method for generating a nominal frequency by means of a PLL circuit in which
a variable output frequency is generated by a voltage-controlled oscillator,
a first comparison frequency is generated by a first frequency divider, while the output frequency is reduced by a first divider factor, in which the size of the first divider factor is a function of the nominal frequency,
a fixed reference frequency is generated by a reference oscillator,
a second comparison frequency is generated by a second frequency divider, while the reference frequency is reduced by a second divider factor,
with a phase detector, with which
the first and second comparison frequencies are compared with one another, in which
the output frequency of the voltage-controlled oscillator is changed as a function of the difference between the first and second comparison frequencies until the output frequency matches the nominal frequency,
wherein, for the coarse adjustment of the nominal frequency, the first and second divider factors are simultaneously lowered by a third common factor, in order to raise the first and second comparison frequencies and then the unchanged first and the second divider factors are used for fine tuning in order to lower the raised first and the second comparison frequencies again:

2. Method according to patent claim 1, wherein the difference between the first and the second comparison frequencies is detected.

3. Method according to patent claim 2, wherein the third factor is selected as a function of the difference.

4. PLL circuit for performing the method according to one of the patent claims 1 to 3 with
a voltage-controlled oscillator,
a first frequency divider,
a reference oscillator,
a phase detector,
wherein the circuit has at least one switching device for changing the first and the second divider factors with an unchanged nominal frequency.

5. PLL circuit according to patent claim 4, wherein the switching device is linked to the phase detector.

6. PLL circuit according to patent claim 4, wherein the switching device simultaneously raises the first and the second divider factors.
